(19) United States
(12) Patent Application Publication
(10) Pub. No.: US 2007/0069300 A1
(43) Pub. Date: Mar. 29, 2007

(54) PLANAR ULTRA-THIN SEMICONDUCTOR-ON-INSULATOR CHANNEL MOSFET WITH EMBEDDED SOURCE/DRAIN

(75) Inventors: Kangguo Cheng, Beacon, NY (US); Dureseti Chidambarrao, Weston, CT (US); Brian Joseph Greene, Yorktown Heights, NY (US); Jack A. Mandelman, Flat Rock, NC (US); Kern Rim, Yorktown Heights, NY (US)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(73) Assignee: INTERNATIONAL BUSINESS MACHINES CORPORATION, Armonk, NY (US)

(21) Appl. No.: 11/162,959

(22) Filed: Sep. 29, 2005

(51) Int. Cl. H01L 29/94

(52) U.S. Cl. 257/368

(57) ABSTRACT

A MOSFET structure includes a planar semiconductor substrate, a gate dielectric and a gate. An ultra-thin (UT) semiconductor-on-insulator channel extends to a first depth below the top surface of the substrate and is self-aligned to and is laterally coextensive with the gate. Source-drain regions, extend to a second depth greater than the first depth below the top surface, and are self-aligned to the UT channel region. A first BOX region extends across the entire structure, and vertically from the second depth to a third depth below the top surface. An upper portion of a second BOX region under the UT channel region is self-aligned to and is laterally coextensive with the gate, and extends vertically from the first depth to a third depth below the top surface, and where the third depth is greater than the second depth.

### BACKGROUND OF THE INVENTION

This invention relates to MOSFET devices and more particularly to Ultra Thin (UT) SEMiconductor-On-Insulator (SEMOI) channel MOSFET devices with the source and drain regions formed in thicker SOI regions of a semiconductor substrate. As employed herein the term SEMiconductor-On-Insulator (SEMOI) is a generic term which refers generally to structures of a semiconductor layer formed on an insulator such Silicon-On-Insulator (SOI), Silicon-Germanium-On-lnsulator (SGOI), and Germanium-On-Insulator (GOI) structures.

A problem encountered, particularly with semiconductor devices with Raised Source/Drain (RSD) and Ultra-Thin (UT) semiconductor-on-insulator devices is that the requirement for low raised source-drain for resistance forces the stressed liners to be located farther away from the channel than would be desired by the designer. For example a UT semiconductor-on-insulator device with an RSD of 30 nm (including silicide) encounters a significant stress loss in the channel. The loss of performance due to the inefficient transfer of stress to the channel is compounded by the competing need to use sidewall insulating spacers which are as thick as possible, to minimize gate to source-drain capacitance. The present invention addresses these problems caused by loss of stress transferred to the channel of UT semiconductor-on-insulator MOSFET devices.

Hsu et al. U.S. Published Patent Application 2005/011 2811 for “Ultra-Thin SOI MOSFET Method and Structure” describes a raised source-drain UTSOI channel MOSFET. The embodiment of Hsu et al. is an example of the above described problem that it has high gate to source-drain capacitance and poor stress transfer to the channel. The lower surface of the UTSOI under channel is coplanar with the lower surface of the source-drain regions, as there is only a single BOX layer of uniform thickness. The source-drain regions are thicker than the channel, but are elevated. However, we have found that it would be preferred that they be recessed rather than elevated.

Wu U.S. Pat. No. 6,060,749 entitled “Ultra-Short Channel Elevated S/D MOSFETS formed on an Ultra-Thin SOI Substrate” and Wu, U.S. Pat. No. 5,956,580 entitled “Method to Form Ultra-Short Channel Elevated S/D MOSFETS on an Ultra-Thin SOI Substrate” describe a UTSOI MOSFET with thicker source-drain regions, but the thicker source-drain regions are elevated above the surface of the channel. To avoid high gate to source-drain capacitance very thick sidewall spacers are used, which results in very poor stress transfer if an overlying stress liner is used.

Choe U.S. Published Patent Application 2005/0067294 entitled “SOI by Oxidation of Porous Silicon” teaches methods of forming an SOI substrate using the porous silicon techniques including ion implantation of a p-type dopant, anodization, and oxidation as is well known in the art. The dopant is selected from the group consisting of p-type dopants such as Ga, Al, B and BF₂, with B and BF₂ being preferred. The resultant structure contains a blanket buried insulator, and another patterned layer of BOX.

Chen et al U.S. Pat. No. 6,429,091 entitled “Patterned Buried Insulator” a patterned buried insulator layers are formed below the future location of the source and drain regions by forming a mask over the body area and implanting a dose of n or p type ions to form buried doped layers. The dopant is implanted to make the silicon easier to etch. Then STI apertures intersecting the buried doped layers are formed by etching. The material which had formed in buried regions, when they were implanted, is then removed by etching through the STI apertures. A light oxidation is followed by a conformal oxide deposition into the STI apertures and also into the buried etched regions, thereby forming BOX regions alongside the STI apertures. Chen et al. does not teach the use of porous silicon to form BOX regions. Furthermore, Chen does not form the UTSOI region under the gate. The semiconductor under the gate is bulk and therefore suffers from the short channel scaling problems that our UTSOI structure solves. Chen does provide source-drain regions which are insulated from the substrate for reduced junction capacitance.

### SUMMARY OF THE INVENTION

It is an object of this invention to form a merging of adjacent layers or patterned layers of Buried OXides (BOX) regions.

It is another object of this invention to provide a structure or method for providing self-aligned BOX regions to any features, as well as features above the substrate.

This invention provides a structure for MOSFET devices and method for fabricating that structure of MOSFET devices such as UT semiconductor-on-insulator devices having embedded thick source-drain regions.

This invention provides a structure and method for fabricating a UT semiconductor-on-insulator MOSFET having embedded thick source-drain regions. The method employs the selective formation of porous silicon regions in a monocrystalline silicon substrate. The porous silicon regions are then converted to silicon oxide, which defines a complex geometry BOX structure. The BOX structure enables embedded thick source-drain structures, resulting in increased channel strain and higher performance, along with an UT silicon layer in a semiconductor-on-insulator structure in which the channel is formed for suppression of deleterious short channel effects. The embedded thick source-drain regions provide reduced series resistance, eliminating the need for raised source-drain (RSD). This allows the use of thinner gate sidewall spacers without incurring a penalty in gate to source-drain capacitance. The use of thinner gate sidewall spacers allows higher stress to be transferred to the channel, resulting in higher performance.

Other advantages of the structure, that are more apparent in the detailed embodiment include:

A. The source-drain regions are self-aligned with the gate conductor and vice versa.

1) The self-alignment eliminates variations in channel strain due to alignment tolerances between the Gate Conductor (GC) mask level and the RX mask level. The RX mask is used to define where transistors are to be formed. The GC mask is employed to define the location of the gate conductors. Note that when reference is made to the tolerance between GC and RX levels, reference is being made as to how precisely the gate conductor (GC) aligns to the edges of the regions containing the transistors (semiconductor-on-insulator body+source/drain regions.)

2) Furthermore, gate to diffusion overlap can now be minimized, resulting in reduced overlap capacitance and higher performance.

3) The embedded source-drain regions can now be placed much closer to the gate edge, resulting in reduced extrinsic source-drain resistance and higher performance.

B. The method uses a replacement gate process, which allows the use of a high-K/Metal gate dielectric for improved device scaling and reduced gate leakage.

In accordance with this invention, a semiconductor substrate with a stack of a gate dielectric layer and a gate conductor is formed on a top surface of the substrate. A SEMiconductor-On-lnsulator (SEMOI) channel region extends to a first depth below the top surface, channel region being self-aligned with and being laterally coextensive with the gate conductor. Source-drain regions are juxtaposed with the channel region formed in the SEMOI substrate. The source-drain regions extend to a second depth below the top surface, and the second depth is greater than the first depth. Preferably, a first Buried OXide (BOX) region formed in the substrate extends laterally across the structure, and vertically from the second depth to a third depth below the top surface of the substrate. The third depth is greater than the second depth. An upper portion of a second BOX region formed in the substrate is positioned under the channel region and is self-aligned with and is laterally coextensive with the gate conductor, and extends vertically from the first depth to a third depth below the top surface of the substrate, and where the third depth is greater than the second depth. A lower portion of a second BOX region under the source-drain regions is self-aligned to the gate conductor, and extends vertically from a fifth depth to a sixth depth below the top surface of the substrate, and where the fifth depth is less than the fourth depth, and where the sixth depth is greater than the fourth depth. The channel region is formed in an Ultra Thin (UT) layer of the substrate; the source-drain regions extend deeper than UT layer of the channel region and being self aligned to the gate conductor; and the top surface of the semiconductor layer is substantially coplanar with upper surfaces of the channel region and the source/drain regions.

Further in accordance with this invention, a MOSFET device comprises an FET device with a gate dielectric and a gate conductor formed on a semiconductor substrate. A first Buried Oxide (BOX) region is formed in the semiconductor substrate defining a lower surface of the semiconductor substrate. An upper, second BOX region is formed in the substrate below the gate electrode and the channel and aligned with the gate conductor. The upper, second BOX region extends above the first BOX region. A channel region is formed in a thin upper layer of the semiconductor substrate above the upper, second BOX region.

In accordance with another aspect of this invention, a MOSFET device is formed upon a semiconductor substrate which has a surface with an FET device formed in a space in the surface of the semiconductor substrate and with a gate dielectric, a gate conductor, and a channel region formed in a thin upper layer of the semiconductor substrate. A first Buried Oxide (BOX) region is formed in the semiconductor substrate below the surface defining a lower surface of the thin upper layer of the semiconductor substrate. An upper, second BOX region is formed in the semiconductor substrate below the gate electrode and the channel and aligned with the gate conductor. The upper, second BOX region extends above the first BOX region. Preferably, the channel extends beneath the gate electrode along sidewalls of the upper, second BOX region. Preferably, the channel is formed in the thin upper layer of the semiconductor substrate above the upper second BOX region. Preferably, source regions and drain regions are self-aligned with the gate conductor. Preferably, source regions and drain regions are embedded in the thin upper layer of the semiconductor substrate above the first BOX region; and the source regions and drain regions are self-aligned with the gate conductor. Preferably, the channel is formed in the thin upper layer of the semiconductor substrate above the upper second BOX region. Source regions and drain regions are embedded in the thin upper layer of the semiconductor substrate; and the source regions and the drain regions are self-aligned with the gate conductor. Preferably, a surface layer of semiconductor oxide or other suitable insulator is formed on the surface of the thin upper layer of the semiconductor substrate aside from the gate electrode. Preferably, source/drain extensions are formed beneath the surface layer of semiconductor oxide or other suitable insulator aside from the gate dielectric. Preferably, a surface layer of semiconductor oxide or other suitable insulator is formed on the surface of the thin upper layer of the semiconductor substrate aside from the gate electrode. Source/drain extensions are formed beneath the surface layer of semiconductor oxide or other suitable insulator aside from the gate dielectric; and the source/drain regions are formed beneath the surface layer of semiconductor oxide or other suitable insulator. Preferably, the channel is formed in the thin upper layer of the semiconductor substrate above the first BOX region. A surface layer of semiconductor oxide or other suitable insulator is formed on the surface of the thin upper layer of the semiconductor substrate aside from the gate electrode above the first BOX region. Source/drain extensions are formed in the thin upper layer of the semiconductor substrate beneath the surface layer of semiconductor oxide or other suitable insulator aside from the gate dielectric and source regions and drain regions are embedded in the thin upper layer of the semiconductor substrate beneath the surface layer of semiconductor oxide or other suitable insulator. The source regions and the drain regions are self-aligned with the gate conductor.

In accordance with still another aspect of this invention, a MOSFET device is formed upon a silicon semiconductor substrate having a surface. An FET device formed in a space in the surface of the silicon semiconductor substrate with a gate dielectric, a gate conductor and a channel region formed in the semiconductor substrate. A first Buried Oxide (BOX) region formed in the silicon semiconductor substrate below the surface defining a lower surface of a thin upper layer of the silicon semiconductor substrate. An upper, second BOX region is formed below the gate electrode and the channel and is aligned with the gate conductor. A lower, second BOX region is formed below the first BOX region aside from the upper, second BOX region and the gate electrode. The upper, second BOX region extends above the first BOX region.

Preferably, the channel extends beneath the gate electrode to sidewalls of the upper, second BOX region. Preferably, the channel is formed in the thin upper layer of the silicon semiconductor substrate above the first BOX region. Preferably, source regions and drain regions are self-aligned with the gate conductor. Preferably, source regions and drain regions are embedded in the thin upper layer of the silicon semiconductor substrate above the first BOX region; and the source regions and drain regions are self-aligned with the gate conductor. Preferably, the channel is formed in the thin upper layer of the silicon semiconductor substrate above the first BOX region. Source regions and drain regions are embedded in the thin upper layer of the silicon semiconductor substrate; and the source regions and the drain regions are self-aligned with the gate conductor. Preferably, a surface layer of silicon oxide or other suitable insulator is formed on the surface of the thin upper layer of the silicon semiconductor substrate aside from the gate electrode. Preferably, source/drain extensions are formed beneath the surface layer of silicon oxide or other suitable insulator aside from the gate dielectric. Preferably, the channel is formed in the thin upper layer of the silicon semiconductor substrate above the first BOX region. A surface layer of silicon oxide or other suitable insulator is formed on the surface of the thin upper layer of the silicon semiconductor substrate aside from the gate electrode above the first BOX region. Source/drain extensions are formed in the thin upper layer of the silicon semiconductor substrate beneath the surface layer of silicon oxide or other suitable insulator aside from the gate dielectric; the source regions and drain regions are embedded in the thin upper layer of the silicon semiconductor substrate beneath the surface layer of silicon oxide or other suitable insulator; and the source regions and the drain regions are self-aligned with the gate conductor.

In accordance with still another aspect of this invention, a method of forming a semiconductor-on-insulator MOSFET device is as follows. Form a gate electrode stack comprising a gate dielectric layer and a gate conductor on a top surface of a semiconductor substrate. Form a first Buried OXide (BOX) region in the substrate below the surface defining a thin upper semiconductor-on-insulator layer of the semiconductor substrate between the surface and the first BOX region. Form an upper, second, BOX region in the semiconductor-on-insulator layer of the semiconductor substrate below both the gate conductor and the channel, the upper, second BOX region being aligned with the gate conductor with the upper, second BOX region extending above the first BOX region to form an Ultra Thin (UT) semiconductor layer thereabove in the semiconductor-on-insulator layer. Form a channel region in the UT layer of the semiconductor substrate above the upper, second, BOX region. Preferably, the BOX regions are formed by the steps comprising implanting dopant into the semiconductor substrate to form doped regions; then forming porous regions in the semiconductor substrate from the doped regions; and converting the porous regions into BOX regions. Preferably, the method includes forming a sacrificial layer; and patterning the sacrificial layer into a dummy gate electrode; forming a gate patterning mask over the dummy gate electrode; then planarizing the gate patterning mask to expose the dummy gate electrode; then etching away the dummy gate electrode to form a gate conductor aperture in the gate patterning mask. Preferably, the semiconductor substrate comprises a silicon semiconductor substrate; a gate dielectric is formed in the gate conductor aperture; and a gate conductor is formed on the gate dielectric in the gate conductor aperture. Preferably, strip the gate patterning mask; then form sidewall spacers on sidewalls of the gate conductor; and form source/drain regions in the semiconductor-on-insulator layer aside from the channel region extending deeper into the SOI layer than the channel region aside from the upper, second BOX region.

### BRIEF DESCRIPTION OF THE DRAWINGS

The foregoing and other aspects and advantages of this invention are explained and described below with reference to the accompanying drawings, in which:

FIGS. 1A-1W show a method of forming a first embodiment of a UT MOSFET or a UT semiconductor-on-insulator MOSFET with high-K/Metal self-aligned replacement gate and embedded source/drains using oxidized porous silicon, in accordance with the method of this invention with a first BOX region which defines a semiconductor-on-insulator structure and a second set of BOX regions. The upper portion of the second set of BOX regions defines the lower surface of the channel which comprises a UT layer in the semiconductor-on-insulator layer and the first BOX region defining the depths of the S/D regions which reach substantially below the depth of the channel. The resulting device is shown in FIG. 1W.

FIG. 2 is a modification of the device of FIG. 1W in which the device is formed on a semiconductor-on-insulator base instead of a bulk silicon semiconductor substrate with a modification of the depth of the lower region of the second BOX structure.

FIG. 3 is a flowchart of showing a sequence of steps A to W of FIGS. 1A to 1W in accordance with the method of this invention.

The invention and objects and features thereof will be more readily apparent from the following detailed description and appended claims when taken with the drawings.

### DESCRIPTION OF THE PREFERRED EMBODIMENT

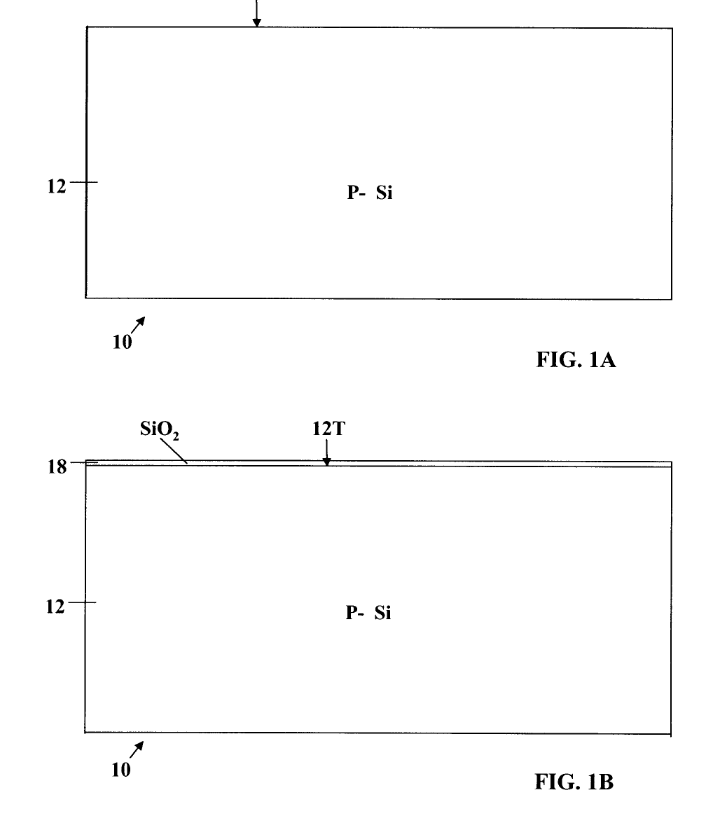

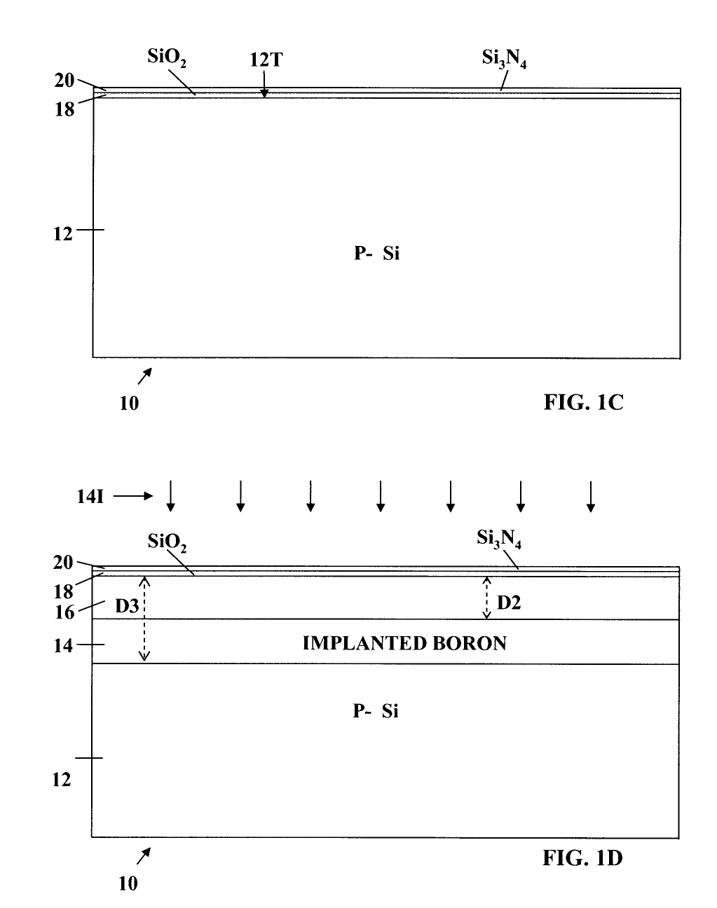

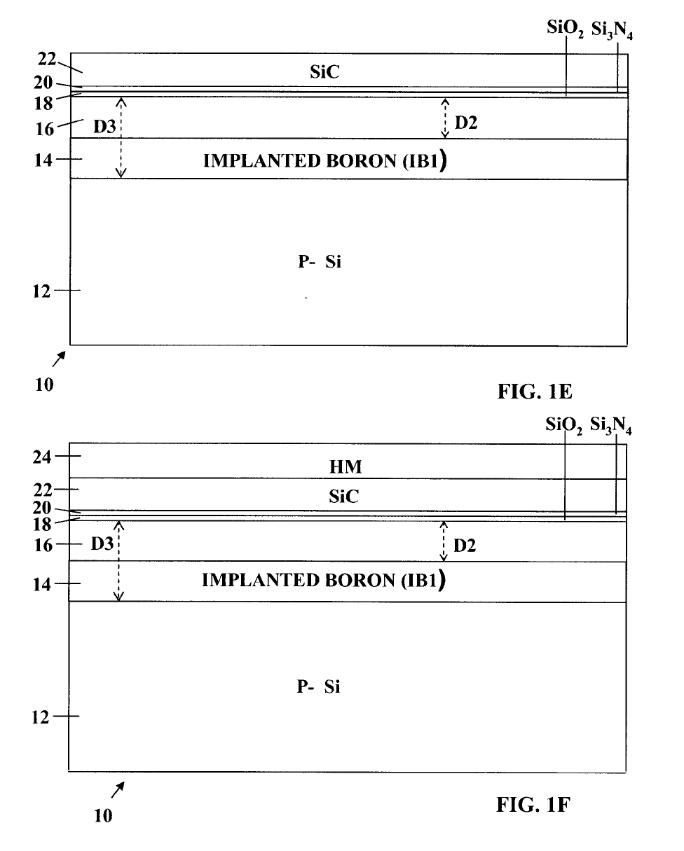

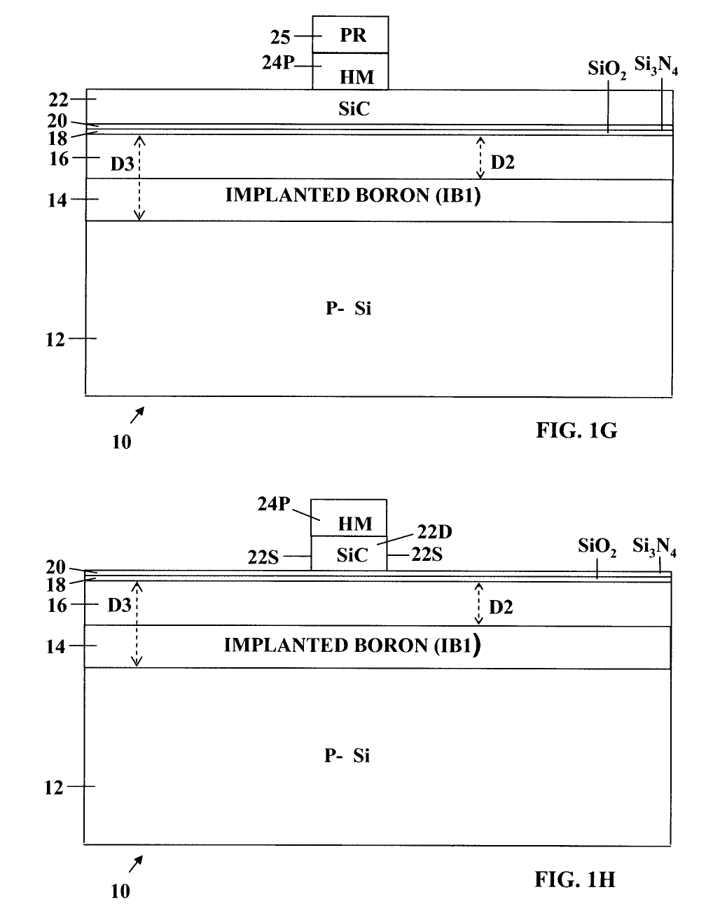

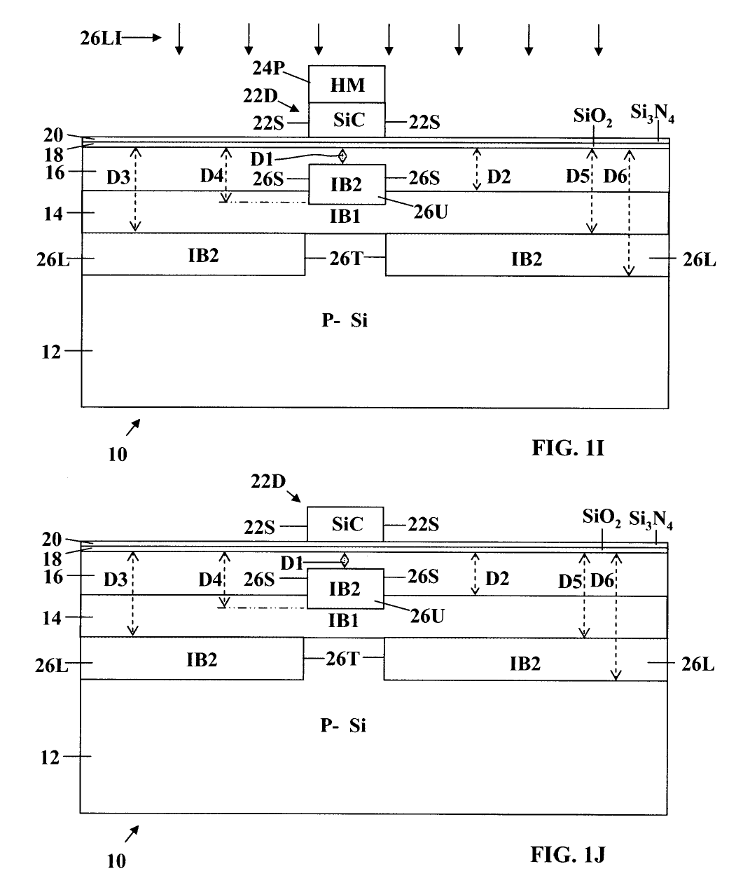

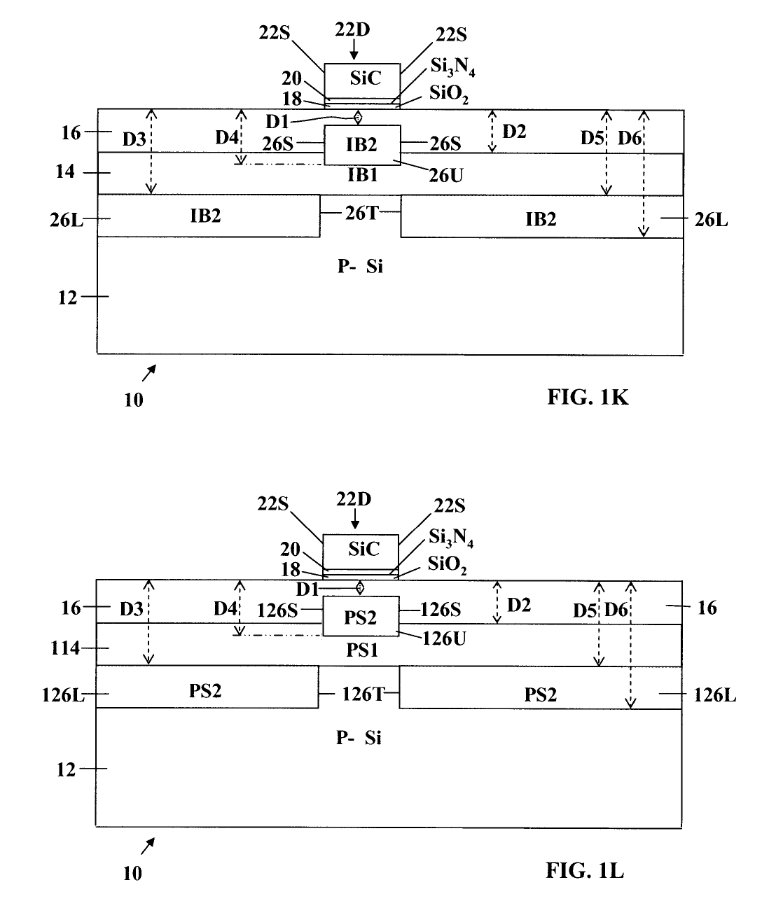

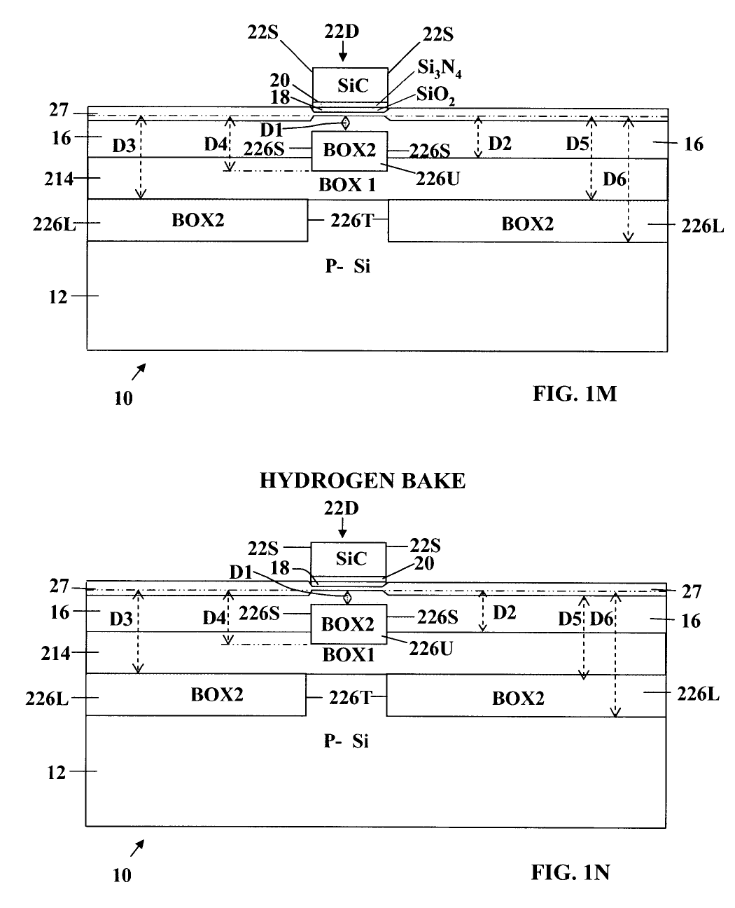

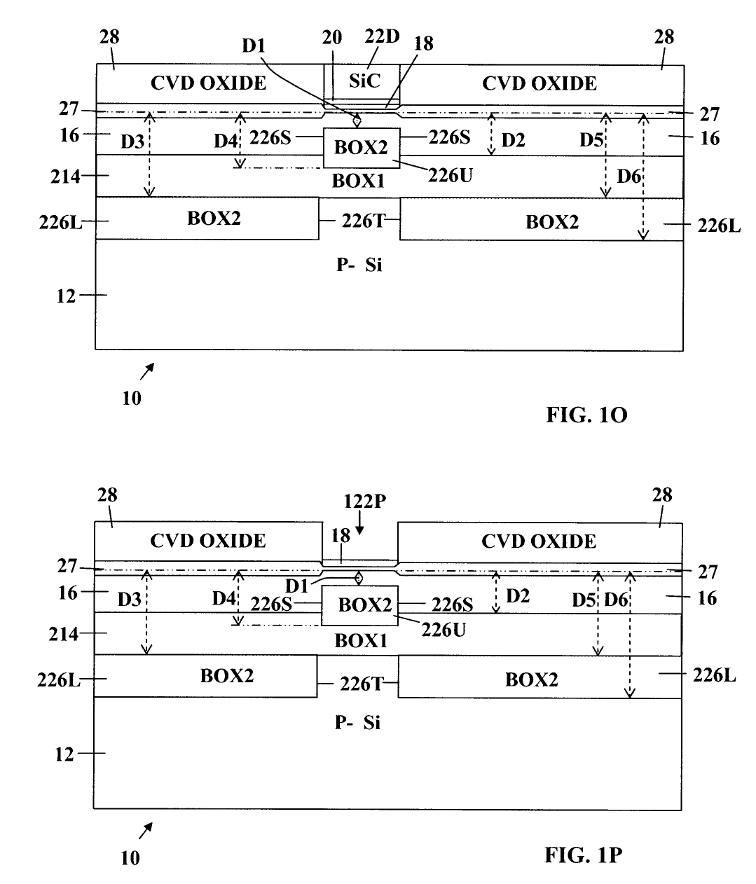

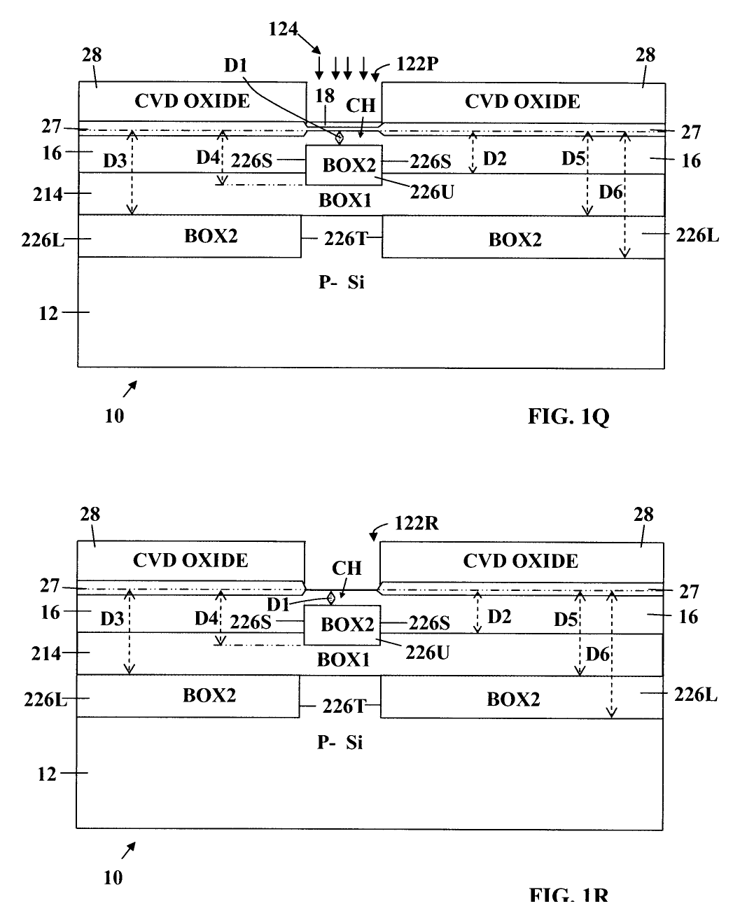

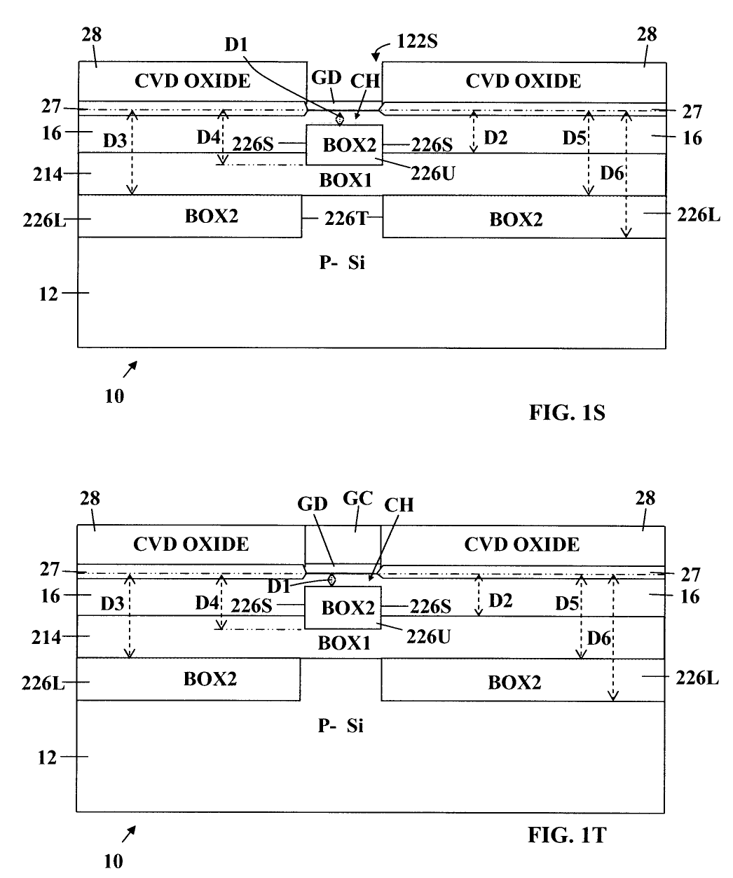

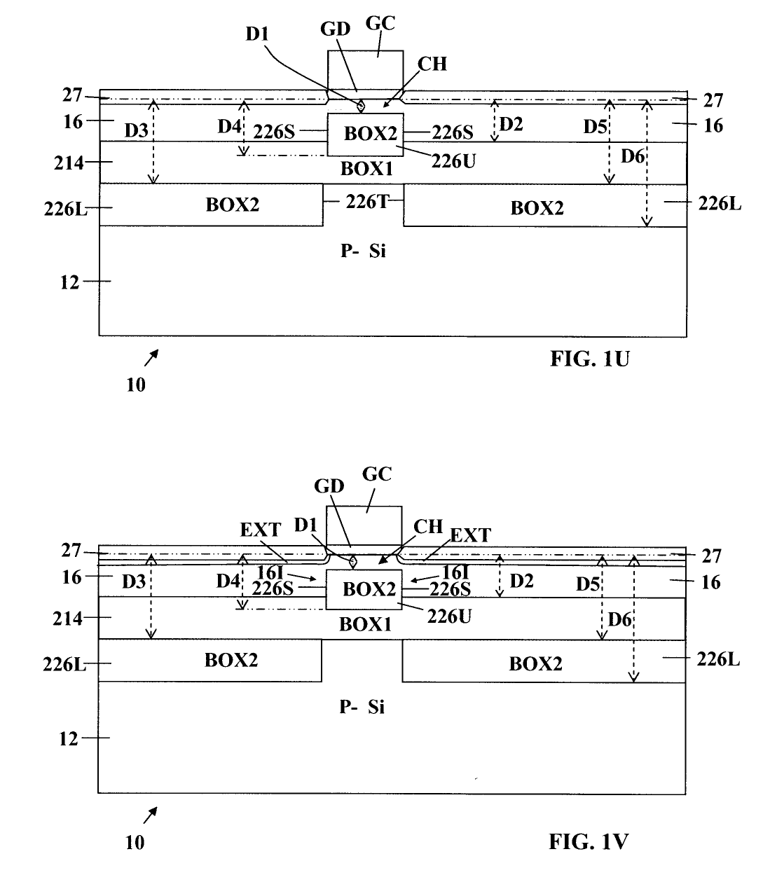

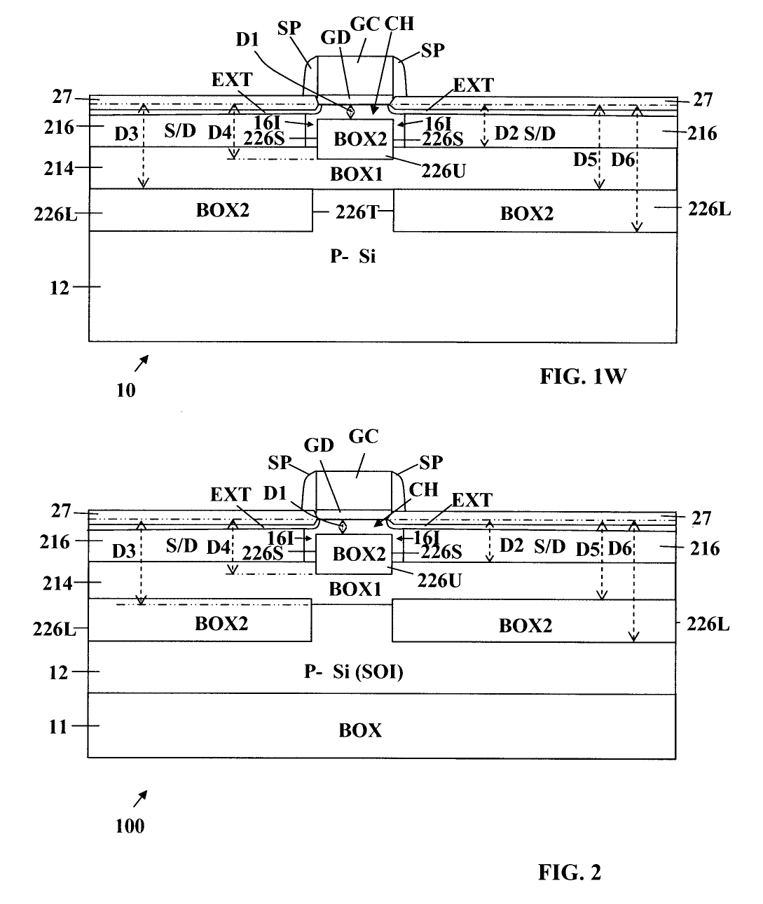

The method of this invention provides for fabrication of a UT or a UT semiconductor-on-insulator MOSFET with high-K/metal self-aligned replacement gate and embedded source/drains using oxidized porous silicon, described below with reference to the FIGS. 1A-1W, FIG. 2 and FIG. 3.

### First Embodiment

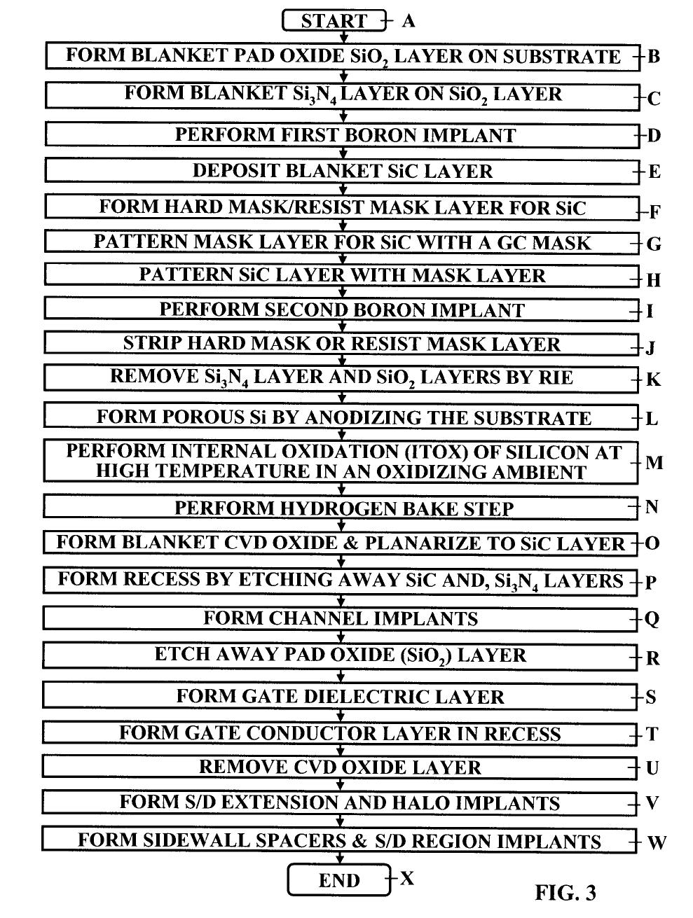

FIG. 1A shows a sectional view of a device 10 in accordance with this invention in an early stage of fabrication in accordance with step A of FIG. 3. The method begins preferably with a substrate 12 composed of conventional bulk semiconductor material selected from group IV periodic table elements and compound semiconductors from groups III-V and II-VI. For example silicon, germanium, silicon-germanium, and silicon-carbide are group IV periodic table elements which may be employed. Compound semiconductors from groups III-V and II-VI include such materials as GaAs, InP, and AlGaAs.

The semiconductor substrate 12 may comprise a thick portion under all the BOX regions of a first semiconductor.

Preferably the substrate 16 that can be formed by epitaxial growth of an upper, second semiconductor region on a substrate composed of a first semiconductor region 12. That is to say that one starts with a laminated semiconductor substrate which does not initially contain a buried oxide layer but which involves a lamination of two materials by epitaxial deposition. Generally, low defect epitaxial growth of a semiconductor layer would limit the substrate and grown layer to being semiconductors from the same periodic table group. For example a first semiconductor layer 12 composed of silicon can be coated with second semiconductor layer 16 composed of SiGe. Alternatively, a first semiconductor layer 12 composed of SiGe can be coated with a second semiconductor layer 16 composed of silicon. Other options are a Si layer 16 on a SiGe substrate 12; a SiC layer 16 on a Si substrate 12; a Ge layer 16 on a Si substrate 12; a GaAlAs 16 on a layer GaAs 12.

Preferably the semiconductor substrate 12 is composed of silicon because of the convenience of working with silicon and the facility of forming porous/oxidized semiconductor regions in accordance with the method of this invention. In the case that substrate 12 is composed of silicon, it is preferred that the silicon is lightly doped (e.g. 1×10¹⁵ cm⁻³-1×10¹⁸ cm⁻³) with n-type or p-type dopant. Alternatively, the substrate 12 can be replaced with a semiconductor-on-insulator substrate 11/12 as shown in FIG. 2, and as described below. The substrate 12 has a top surface 12T.

Formation of Pad Oxide and Nitride Layers

FIG. 1B shows the device 10 of FIG. 1A after formation in accordance with step B of FIG. 3 of a blanket thin pad oxide (SiO₂) layer 18 with a thickness of about 1 nm-5 nm on the top surface 12T of the bare semiconductor (silicon) substrate 12. Conventional means may be used to form the thin pad oxide layer 18, such as thermal oxidation.

FIG. 1C shows the device 10 of FIG. 1B after formation in accordance with step C of FIG. 3 of a blanket silicon nitride (Si₃N₄) layer 20 with a thickness of about 1 nm-5 nm on the thin pad oxide layer 18. Conventional means may be used to form the silicon nitride layer 20, such as a CVD nitride process.

Initial Implantation of Boron Dopant Ions

FIG. 1D shows the device 10 of FIG. 1C during implanting in accordance with step D of FIG. 3 of a buried IB1 region 14 in the substrate 12. The buried IB1 region 14 is doped with boron dopant ions 14I in accordance with step 33 of FIG. 3. The buried IB1 region 14 has a peak concentration of dopant in the range from about 1×10¹⁹ cm⁻³ to about 5×10²⁰ cm⁻³, although concentrations less than or greater than the above mentioned range may be used. Since the depth of the upper edge of the buried IB1 region 14 will determine the depth of the embedded source-drain regions (S/D) shown in FIG. 1T, the energy of the implant should be adjusted accordingly. Optionally, a block mask can be used to confine the implant to selected regions of the substrate. A thin semiconductor (silicon) region 16 of the semiconductor (silicon) substrate 12 remains in the surface of the semiconductor (silicon) substrate 12 above the buried IB1 region 14. The thin semiconductor (silicon) region 16 will become the semiconductor of a semiconductor-on-insulator structure above the insulation layer formed by BOX1 region 214 of FIG. 1L. Preferably the upper edge (top surface) of the buried IB1 region 14 is located a second depth D2 (about 50 nm to 300 nm) beneath the top surface 12T of the thin silicon region 16 of the silicon substrate 12. The lower edge (bottom surface) of the buried IB1 region 14 is a third depth D3 below the top surface of the thin semiconductor region 16 of the semiconductor substrate 12.

Formation of Blanket Sacrificial SiC Layer

FIG. 1E shows the device 10 of FIG. 1D after deposition in accordance with step E of FIG. 3 of a blanket sacrificial layer 22 of a silicon carbide (SiC). The thickness of the SiC layer 22 is preferably between 30 nm and 300 nm.

Formation of Blanket Hard Mask Layer

FIG. 1F shows the device 10 of FIG. 1E after step F of FIG. 3 in which a hard mask layer 24 (e.g. silicon dioxide, silicon nitride) is deposited over the sacrificial layer 22. The hard mask layer 24 preferably has a thickness from about 50 nm to about 300 nm.

Patterning of Hard Mask Layer

FIG. 1G shows the device 10 of FIG. 1F after performing step G of FIG. 3 of patterning the hard mask material layer 24 by first forming a narrow gate conductor (GC) mask 25 (which may be composed of photoresist) over the hard mask layer 24. The GC mask 25 has the width desired for a gate conductor GC. Then in a subtractive process, the hard mask layer 24 is formed into the patterned hard mask 24P of the GC mask 25.

Patterning of Sacrifical SiC Layer

FIG. 1H shows the device 10 of FIG. 1G after performing step H of FIG. 3 of patterning the sacrificial SiC layer 22 into sacrificial SiC dummy gate 22D using patterned hard mask layer 24P as a mask for the RIE of the SiC selective to the underlying silicon nitride. Alternatively, photoresist can be used as a mask for the RIE of the SiC selective to the underlying silicon nitride. Methods exist for the RIE of SiC selective to insulators, e.g. U.S. Pat. No. 6,670,278 of Li et al entitled “Method of Plasma Etching of Silicon Carbide.” Basically, the SiC is patterned using a plasma formed by CH₃F and an oxygen containing species. The resulting sacrificial SiC dummy gate 22D has vertical sidewalls 22S spaced apart by the desired width of the gate conductor GC that will be formed, as shown in FIG. 1T.

Second Implantation of Boron Ions Uppermost Below SiC Mask and Lower Elsewhere.

FIG. 1I shows the device 10 of FIG. 1H after performing step I of FIG. 3 (following the formation of sacrificial SiC dummy gate 22D in step H) of forming P-doped, second, upper IB2 regions 26U and lower IB2 regions 26L by performing a second implant with boron dopant ions 261. The energy of the second boron implant is greater than that of the first, resulting in the implanted, second, upper and lower IB2 regions 26U/26L shown in FIG. 1H.

The top surface of the upper IB2 region 26U is located a first depth D1 below the top surface of the thin semiconductor (silicon) region 16 of the semiconductor (silicon) substrate 12. The bottom surface of the upper IB2 region 26U is located a fourth depth D4 below the top surface of the thin semiconductor region 16 of semiconductor substrate 12.

The top surface of the lower IB2 region 26L is located a fifth depth D5 below the top surface of the thin semiconductor region 16 of the semiconductor substrate 12. The bottom surface of the lower IB2 region 26L is located a sixth depth D6 below the top surface of the thin semiconductor region 16 of semiconductor substrate 12.

The upper IB2 region 26U is located centrally directly below sacrificial SiC dummy gate 22D in the upper surface of the buried IB1 region 14. The implanted boron has passed through the thickness of the hard mask HM 24P and the sacrificial SiC dummy gate 22D. The energy of the second boron implant is adjusted so that the location of the top surface of the upper IB2 region 26U can be controlled to obtain the desired thickness of the UT semiconductor-on-insulator layer under the gate region, which is to be formed in the location of the sacrificial SiC dummy gate 22D. The sidewalls 26S of the upper IB2 region 26U, which extend above the upper surface of buried IB1 region 14 are aligned with the sidewalls 22S of the SiC dummy gate 22D.

The lower IB2 regions 26L are located laterally, below the buried IB1 region 14 aside from the sacrificial SiC dummy gate 22D and the upper IB2 region 26U, and are shown located below the level of the buried IB1 region 14. The lower IB2 regions 26L, which are spaced apart by about the width of the sacrificial SiC dummy gate 22D, have sidewalls 26T aligned with the sidewalls 26S of the sacrificial SiC dummy gate 22D and the sidewalls 26S of the upper IB2 region 26U.

Stripping of Hard Mask

FIG. 1J shows the device 10 of FIG. 1J after performing step J of FIG. 3 in which the hard mask 22M (or resist mask) has been stripped by the process of isotropic etching and/or chemical stripping. If the hard mask 24P is composed of silicon oxide, a buffered HF etch is typically used. For a silicon nitride hard mask 24P, a RIE comprising SF₆ (sulfur hexafluoride) is preferred to avoid undercutting the silicon nitride layer 20 under the sacrificial SiC dummy gate 22D. In the case of a silicon nitride hard mask 24P, exposed regions of the silicon nitride layer 20 would also be removed. If the etch mask 24P for the sacrificial SiC dummy gate 22D is composed of a resist material, an appropriate chemical resist stripper or an oxygen plasma could be used to strip the resist etch mask 24P.

Remove Exposed Portions of Nitride and Oxide

FIG. 1K shows the device 10 of FIG. 1J after performing step K of FIG. 3 in which the exposed portions of the thin silicon nitride layer 20 and the silicon oxide of the thin pad oxide layer 18 aside from the sacrificial SiC dummy gate 22D have been removed by RIE (Reactive Ion Etching) as will be well understood by those skilled in the art selective to the sacrificial SiC dummy gate 22D and the silicon layer 16. There are portions of the thin silicon nitride layer 20 and the thin pad oxide layer 18 which are protected from removal during this step, as they lie beneath the sacrificial SiC dummy gate 22D.

Anodize Semiconductor Substrate to Convert Boron Implanted Regions into Porous Semiconductor Material

FIG. 1L shows the device 10 of FIG. 1K after performing step L of FIG. 3 in which an anodization process has been applied to the semiconductor (silicon) substrate 12. Then the semiconductor (silicon) substrate 12 and a platinum electrode are placed in a bath of hydrogen fluoride (HF) solution with a positive terminal from a current source connected to the semiconductor substrate 12 and a negative terminal from a current source connected to the a platinum electrode. The HF solution, in the presence of the anodization current readily diffuses through the single crystal semiconductor (silicon) to the higher concentration P-doped regions, where it reacts with the semiconductor material (silicon) to form porous semiconductor (silicon) regions PS1/PS2. A buried PS1 region 114 is formed from buried IB1 region 14. An upper porous semiconductor (silicon) buried PS2 region 126U (with sidewalls 126S located in the position of former sidewalls 26S) is formed from upper IB2 region 26U. A pair of lower porous semiconductor (silicon) buried PS2 regions 126L (with sidewalls 126T located in the position of former sidewalls 26T) are formed from lower IB2 regions 26L. The anodization current is in the range of 1 mA/cm² to 100 mA/cm², depending on the desired porosity of the structure of the device 10. Then the process of formation of the porous regions in the semiconductor substrate 12 has been completed.

Perform Internal Oxidation to Convert of Porous Silicon Regions into Box Regions

Referring to FIG. 1M the device 10 of FIG. 1L is shown after it has been subjected in step M in FIG. 3 to an ITOX (InTernal OXidation of silicon) process at a temperature between about 800° C. and 1330° C. in an oxidizing ambient. During the ITOX process two things happen. A thin layer 27 of silicon oxide 27 is formed in the surface of the thin upper semiconductor (silicon) layer 16 (which has not been implanted with boron) aside from the sacrificial stack which is capped by the sacrificial SiC dummy gate 22D, i.e. aside from the sidewalls 22S thereof.

In addition to formation of the thin layer 27 of silicon oxide 27, the porous semiconductor (silicon) regions, which have been implanted with boron, are more readily oxidized to form several BOX (BOX) regions 226U/226L. The porous semiconductor (silicon) buried PS1 region 114 is converted into a BOX1 region 214. The upper porous semiconductor (silicon) buried PS2 region 126U is converted into a commensurate upper BOX region 226U located in the same position with sidewalls 226S located in the position of former sidewalls 126S aligned with the sidewalls 22S of the sacrificial SiC dummy gate 22D. The pair of lower porous buried PS2 regions 126L are converted into a commensurate pair of lower BOX regions 226L have sidewalls 226T located in the position of former sidewalls 126T. Each of the silicon nitride layer 20 and the sacrificial SiC dummy gate 22D are composed of a material which has a very high melting point. Thus, the silicon nitride layer 20 and the sacrificial SiC dummy gate 22D do not degrade during the ITOX step.

Hydrogen Bake to Remove Boron form Silicon

FIG. 1N shows the device 10 of FIG. 1M after performing step N of FIG. 3 in which the substrate 12 is subject to a hydrogen bake, which removes most of the implanted boron remaining in the silicon. The hydrogen bake is an important step since it provides sufficiently low doping concentration to allow subsequent definition of device doping regions (e.g. channel, halos, source-drain). The hydrogen bake may be conducted at temperatures ranging from about 800° C. to 1,000° C. for times ranging from 30 seconds to 30 minutes.

Form Planarized, Gate Patterning Layer on Surface of Device

FIG.10 shows the device 10 of FIG. 1N after step 44 in which a gate patterning layer 28, preferably composed of silicon oxide layer is formed by Chemical Vapor Deposition (CVD) and planarized to the level of the top surface of the sacrificial SiC dummy gate 22D.

Remove Sacrifical SiC Pattern from Device to Form Gate Electrode Aperature

FIG. 1P shows the device 10 of FIG. 1O after step P in which the sacrificial SiC dummy gate 22D has been removed by etching with an etchant selective to the gate patterning, silicon oxide layer 28 followed by etching away the remainder of the silicon nitride layer 20 which had been protected during step 40 by being located below the sacrificial SiC dummy gate 22D. Methods for plasma etching SiC selective to oxide and nitride have been disclosed by Li et al in U.S. Pat. No. 6,670,278 and are incorporated herein by reference. Then the thin silicon nitride layer 20 is removed. The removal of the sacrificial SiC dummy gate 22D and the silicon nitride layer 20 leaves a recess in the gate patterning, silicon oxide layer 28 for use as a gate electrode patterning aperture 122P reaching down to the top surface of the thin pad oxide layer 18.

Perform Channel Implant through Gate Electrode Aperature

FIG. 1Q shows the device 10 of FIG. 1P during step Q of FIG. 3 when channel implant ions 124 are being implanted through the recess or aperture 122P and through the thin pad oxide layer 18 at the base thereof into the thin upper semiconductor layer 16 to form a channel region CH in the portion of the thin upper semiconductor layer 16 adjacent to aperture 122A and extending down alongside the sidewalls 226S of the upper BOX2 region 226U. The channel regions CH extends to a first depth below the top surface of the upper semiconductor layer 16, which is the upper surface of the substrate of device 10.

Remove Pad Oxide Layer from Gate Electrode Aperature

FIG. 1R shows the device 10 of FIG. 1Q after step R of FIG. 3 during which the exposed thin pad oxide layer 18 at the bottom of the aperture 1 12P was removed forming a deepened recess or aperture 122R extending down to the surface of the thin upper semiconductor layer 16 where the channel region CH is formed.

Form Gate Dielectric Layer over the Exposed Channel Region

FIG. 1S shows the device 10 of FIG. 1R after step S of FIG. 3 during which a gate dielectric layer GD was formed on top of the channel region CH (in the upper thin silicon layer 16) at the base of the gate patterning aperture 122R forming a shallower recess or gate patterning aperture 122S in the gate patterning, silicon oxide layer 28. The gate dielectric layer GD may comprise a material selected from the group consisting of silicon oxide, silicon oxynitride, and high-K dielectric or a combination thereof.

Deposit Gate Conductor into Gate Aperture Over Gate Dielectric

FIG. 1T shows the device 10 of FIG. 1S after step T of FIG. 3 during which a gate conductor GC was deposited, on the gate dielectric layer GD filling the recess or gate patterning aperture 122S. The gate conductor GC, which has been planarized to the top surface of the CVD oxide layer 28, may be composed of a material selected from the group consisting of a metal (e.g. tungsten), a silicide (e.g. tungsten or nickel silicide), and doped polysilicon, or a combination thereof.

Strip Gate Patterning Layer

In step U of FIG. 3, as shown by FIG. 1U, the CVD oxide layer 28 of FIG. 1T has been removed selective to the gate conductor GC. Preferably an HF solution is used as the etchant, as it etches CVD oxide 28 many times faster than thermal oxide 27. A substantial portion of the underlying thin silicon oxide layer 27 may remain after this step of oxide etching, because its density is greater than that of CVD oxide 28. It is preferable to use a directional etch (e.g. RIE) towards the end of this etch process to avoid the undercutting of the gate conductor GC and etching into the gate dielectric GD. Optionally, silicon oxide layer 27 may be completely removed by continued etching. A screen oxide would then be grown on the surface of region 16, prior to source-drain implants.

Form Source/Drain Extensions

In step V of FIG. 3, as shown by FIG. 1V, source-drain extension implants EXT and halos (not shown for convenience of illustration are added at this time into the device 10 of FIG. 1U.

Form Sidewall Spacers and Perform S/D Implantation

In step W of FIG. 3, as shown by FIG. 1W, sidewall spacers SP are formed on the sidewalls of the gate conductor GC of FIG. 1V. Typically sidewall spacers SP are composed of silicon oxide or silicon nitride, which is formed by well known deposition and RIE methods. Then a conventional step is performed of source-drain S/D implantation to form source/drain regions 216 that are self-aligned with the gate conductor GC. Note that the source/drain regions 216 extend well below the channel CH which is formed above the upper BOX region 226U, whereas the source/drain regions reach down to the BOX1 region 214, which has an upper surface substantially lower than the top surface of the upper BOX region 226U. The source/drain regions 216 extend to a second depth D2 greater than the first depth D1 below the top surface of the upper silicon layer 16.

Various depths of the edges of the buried BOX regions 226U/226L and 121 in the device 10 are summarized next. The upper edge (top surface) of BOX2 region 226U is a first depth D1 below the top surface of the thin semiconductor region 16 of semiconductor substrate 12. The upper edge (top surface) of BOX1 region 214 is a second depth D2 below the top surface of thin semiconductor region 16 of semiconductor substrate 12. The lower edge (bottom surface) of the BOX1 region 214 is a third depth D3 below the top surface of thin semiconductor region 16 of semiconductor substrate 12. The lower edge (bottom surface) of BOX2 region 226U is a fourth depth D4 below the top surface of the thin semiconductor region 16 of the semiconductor substrate 12. The upper edge (top surface) of BOX2 region 226L is a fifth depth D5 below the top surface of thin semiconductor region 16 of semiconductor substrate 12. The lower edge (bottom surface) of BOX2 region 226S is a sixth depth D6 below the top surface of the thin semiconductor region 16 of semiconductor substrate 12. While the depths D1-D6 may vary as a function of processing, to avoid prolixity and confusion, the depths are assumed to be substantially the same.

While in FIGS. 1I to 1W the dimensions D3 and D5 appear in the schematic drawings to be equal, that is not necessarily the case in a practical embodiment. However, it is preferred that D5 shall not exceed D3 and D3 must be more than D2. Preferably D3 is greater than D4. The important factor is that D1 is substantially less than D2 so that the source/drain regions S/D are deeper in the ultra thin semiconductor region 16 than the channel CH.

Conventional processing continues from this point, which includes formation of interlevel dielectric layers, conductive studs, and wiring levels. The process ends with step X of FIG. 3. Note that the steps A-X of FIG. 3 are described above in combination with the description of FIGS. 1A-1W.

### Second Embodiment

FIG. 2 shows a second embodiment of this invention comprising a device 100 which is similar to the device 10 of FIG. 1W, but which has been modified by the formation of the structure on a BOX substrate 11 as compared with the bulk substrate 11 of FIGS. 1A-1W. In addition, the lower BOX regions 226L are shown overlapping the BOX1 region 214 so that the depth D5 of the top surface of the lower BOX regions 226L is less than the depth D3 of the top surface of the BOX1 region 214. The device 100 can be manufactured in accordance with the steps shown in FIG. 3.

While this invention has been described in terms of the above specific embodiment(s), those skilled in the art will recognize that the invention can be practiced with modifications within the spirit and scope of the appended claims, i.e. that changes can be made in form and detail, without departing from the spirit and scope of the invention. Accordingly all such changes come within the purview of the present invention and the invention encompasses the subject matter of the following claims.

What is claimed is:

1. A MOSFET structure comprising:
a semiconductor substrate with a stack of a gate dielectric layer and a gate conductor formed on a top surface of said substrate;
a semiconductor-on-insulator channel region extending to a first depth below said top surface, channel region being self-aligned with and being laterally coextensive with said gate conductor; and
source-drain regions juxtaposed with said channel region formed in said semiconductor-on-insulator substrate;
said source-drain regions extending to a second depth below said top surface; and
where said second depth is greater than said first depth.

2. The MOSFET of claim 1 wherein a first Buried OXide (BOX) region formed in said substrate extends laterally across said structure, and vertically from said second depth to a third depth below said top surface of said substrate; and where said third depth is greater than said second depth.

3. The MOSFET of claim 2 where an upper portion of a second BOX region formed in said substrate is positioned under said channel region and is self-aligned with and is laterally coextensive with said gate conductor, and extends vertically from said first depth to a third depth below said top surface of said substrate, and where said third depth is greater than said second depth.

4. The MOSFET of claim 2 wherein a lower portion of a second BOX region under said source-drain regions is self-aligned to said gate conductor, and extends vertically from a fifth depth to a sixth depth below said top surface of said substrate, and where said fifth depth is less than said fourth depth, and where said sixth depth is greater than said fourth depth.

5. The MOSFET of claim 1 wherein:
said channel region being formed in an Ultra Thin (UT) layer of said substrate;
said source-drain regions extending deeper than UT layer of said channel region and being self aligned to said gate conductor; and
said top surface of said semiconductor layer being substantially coplanar with upper surfaces of said channel region and said source/drain regions.

6. A MOSFET device comprising:
an FET device with a gate dielectric and a gate conductor formed on a semiconductor substrate;
a first Buried Oxide (BOX) region is formed in said semiconductor substrate defining a lower surface of said semiconductor substrate;
an upper, second BOX region is formed in said substrate below said gate electrode and said channel and aligned with said gate conductor;
said upper, second BOX region extending above said first BOX region; and
a channel region formed in a thin upper layer of said semiconductor substrate above said upper, second BOX region.

7. The device of claim 6 wherein said channel extends beneath said gate electrode along sidewalls of said upper, second BOX region.

8. The device of claim 6 wherein said channel is formed in said thin upper layer of said semiconductor substrate above said upper, second BOX region.

9. The device of claim 6 wherein source regions and drain regions are self-aligned with said gate conductor.

10. The device of claim 6 wherein:
source regions and drain regions are embedded in said thin upper layer of said semiconductor substrate above said first BOX region; and
said source regions and drain regions are self-aligned with said gate conductor.

11. The device of claim 6 wherein:
said channel is formed in said thin upper layer of said semiconductor substrate above said upper second BOX region;
source regions and drain regions are embedded in said thin upper layer of said semiconductor substrate; and
said source regions and said drain regions are self-aligned with said gate conductor.

12. The device of claim 6 wherein a surface insulating layer is formed on said surface of said thin upper layer of said semiconductor substrate aside from said gate electrode.

13. The device of claim 12 wherein source/drain extensions are formed beneath said surface insulating layer aside from said gate dielectric.

14. The device of claim 6 wherein:
a surface insulating layer is formed on said surface of said thin upper layer of said semiconductor substrate aside from said gate electrode;
source/drain extensions are formed beneath said surface insulating layer aside from said gate dielectric; and
said source/drain regions are formed beneath said surface insulating layer.

15. The device of claim 6 wherein:
said channel is formed in said thin upper layer of said semiconductor substrate above said first BOX region;
a surface insulating layer is formed on said surface of said thin upper layer of said semiconductor substrate aside from said gate electrode above said first BOX region;
source/drain extensions are formed in said thin upper layer of said semiconductor substrate beneath said surface insulating layer aside from said gate dielectric;
source regions and drain regions are embedded in said thin upper layer of said semiconductor substrate beneath said surface insulating layer; and
said source regions and said drain regions are self-aligned with said gate conductor.

16. A MOSFET device formed upon a silicon semiconductor substrate comprising:
said silicon semiconductor substrate having a surface;
an FET device formed in a space in said surface of said silicon semiconductor substrate with a gate dielectric, a gate conductor and a channel region formed in said semiconductor substrate;
a first Buried Oxide (BOX) region formed in said silicon semiconductor substrate below said surface defining a lower surface of a thin upper layer of said silicon semiconductor substrate;
an upper, second BOX region formed below said gate electrode and said channel and aligned with said gate conductor;
a lower, second BOX region formed below said first BOX region aside from said an upper, second BOX region and said gate electrode; and
said upper, second BOX region extending above said first BOX region.

17. The device of claim 16 wherein said channel extends beneath said gate electrode to sidewalls of said upper, second BOX region.

18. The device of claim 16 wherein said channel is formed in said thin upper layer of said silicon semiconductor substrate above said first BOX region.

19. The device of claim 16 wherein source regions and drain regions are self-aligned with said gate conductor.

20. The device of claim 16 wherein:
source regions and drain regions are embedded in said thin upper layer of said silicon semiconductor substrate above said first BOX region; and
said source regions and drain regions are self-aligned with said gate conductor.

21. The device of claim 16 wherein:
said channel is formed in said thin upper layer of said silicon semiconductor substrate above said first BOX region;
source regions and drain regions are embedded in said thin upper layer of said silicon semiconductor substrate; and
said source regions and said drain regions are self-aligned with said gate conductor.

22. The device of claim 16 wherein a surface layer of silicon oxide is formed on said surface of said thin upper layer of said silicon semiconductor substrate aside from said gate electrode.

23. The device of claim 22 wherein source/drain extensions are formed beneath said surface layer of silicon oxide aside from said gate dielectric.

24. The device of claim 16 wherein:
said channel is formed in said thin upper layer of said silicon semiconductor substrate above said first BOX region;
a surface layer of silicon oxide is formed on said surface of said thin upper layer of said silicon semiconductor substrate aside from said gate electrode above said first BOX region;
source/drain extensions are formed in said thin upper layer of said silicon semiconductor substrate beneath said surface layer of silicon oxide aside from said gate dielectric;
source regions and drain regions are embedded in said thin upper layer of said silicon semiconductor substrate beneath said surface layer of silicon oxide; and
said source regions and said drain regions are self-aligned with said gate conductor.

25. A method of forming a semiconductor-on-insulator MOSFET device comprising:
forming a gate electrode stack comprising a gate dielectric layer and a gate conductor on a top surface of a semiconductor substrate;
forming a first Buried OXide (BOX) region in said substrate below said surface defining a thin upper semiconductor-on-insulator layer of said semiconductor substrate between said surface and said first BOX region;
forming an upper, second, BOX region in said semiconductor-on-insulator layer of said semiconductor substrate below both said gate conductor and said channel,
said upper, second BOX region being aligned with said gate conductor with said upper, second BOX region extending above said first BOX region to form an Ultra Thin (UT) semiconductor layer thereabove in said semiconductor-on-insulator layer; and
forming a channel region in said UT layer of said semiconductor substrate above said second, BOX region.

26. The method of claim 25 wherein said BOX regions are formed by the steps comprising:
implanting dopant into said semiconductor substrate to form doped regions;
then forming porous regions in said semiconductor substrate from said doped regions; and
converting said porous regions into BOX regions.

27. The method of claim 26 including:
forming a sacrificial layer; and
patterning said sacrificial layer into a dummy gate electrode.

28. The method of claim 27 wherein:
forming a gate patterning mask over said dummy gate electrode;
then planarizing said gate patterning mask to expose said dummy gate electrode;
then etching away said dummy gate electrode to form a gate conductor aperture in said gate patterning mask.

29. The method of claim 28 wherein:
said semiconductor substrate comprises a silicon semiconductor substrate;
a gate dielectric is formed in said gate conductor aperture; and
a gate conductor is formed on said gate dielectric in said gate conductor aperture.

30. The method of claim 29 including the steps of:
stripping said gate patterning mask;
then forming sidewall spacers on sidewalls of said gate conductor; and
forming source/drain regions in said semiconductor-on-insulator layer aside from said channel region extending deeper into said SOI layer than said channel region aside from said second BOX region.
